(19) United States
(12) Patent Application Publication
(10) Pub. No.: US 2026/0253626 A1
(43) Pub. Date: Aug. 27, 2026

(54) CLOCK GATING TECHNIQUES FOR MEMORY SUBSYSTEMS

(71) Applicant: Marvell Asia Pte Ltd, Singapore (SG)

(72) Inventor: Hyunjin Noh, Newmarket (CA)

(73) Assignee: Marvell Asia Pte Ltd, Singapore (SG)

(21) Appl. No.: 19/539,680

(22) Filed: Feb. 13, 2026

Related U.S. Application Data
(60) Provisional application No. 63/761,877, filed on Feb. 21, 2025.

(51) Int. Cl. G11C 7/22

(52) U.S. Cl. CPC G11C 7/222; G11C 7/22

(57) ABSTRACT

Examples described herein include clock gating logic to gate a clock signal from the memory controller when the memory controller interface is idle. The clock gating logic may ungate the clock signal for a duration when it detects that the memory controller has received a memory access request. The duration that the clock is ungated for may be based on timing parameters obtained from the memory controller, such as latency values and/or other timing parameters. Gating the clock signal when the memory controller’s interface with a requester is idle may result in significant power savings in the memory subsystem.

### PRIORITY APPLICATION

This patent application claims priority to and receives benefit from U.S. Provisional Application No. 63/761,877, titled "Clock Gating for Power Reduction in Memory Solution,” filed on Feb. 21, 2025. The U.S. Provisional Application is hereby incorporated by reference in its entirety.

### BACKGROUND

Dynamic Random-Access Memory (DRAM) is a widely used volatile memory technology that stores data as electrical charge in capacitive storage cells, and which implements refresh operations to maintain data integrity. High Bandwidth Memory (HBM) is a DRAM technology that provides significantly increased bandwidth compared to conventional DRAM architectures through three-dimensional stacking of multiple DRAM dies on a base logic die using through-substrate vias (TSVs). The resulting HBM stack is typically integrated with a host processor, application-specific integrated circuit (ASIC), or other compute die using advanced packaging technologies such as silicon interposers.

Despite its performance advantages, HBM presents several technical challenges. For example, power consumption remains a critical constraint, as the combination of multiple active DRAM dies, physical layer (PHY) circuitry, and high aggregate bandwidth can result in significant power draw. Additionally, the tight timing margins required for high-speed operation typically lead to complex calibration and training procedures to compensate for process, voltage, and temperature variations across the interface between the memory controller and the HBM stack.

### BRIEF DESCRIPTION OF THE DRAWINGS

Embodiments will be readily understood by the following detailed description in ‎conjunction with the accompanying drawings. To facilitate this description, like reference ‎numerals designate like structural elements. Embodiments are illustrated by way of ‎example, and not by way of limitation, in the figures of the accompanying drawings.

FIG. 1 illustrates an exemplary system including a high bandwidth memory (HBM) stack, according to some embodiments of the disclosure.

FIG. 2 illustrates an exemplary system including an HBM stack in which clock gating techniques may be implemented, according to some embodiments of the disclosure.

FIG. 3A illustrates a block diagram of an example of a base die with an integrated memory controller, according to some embodiments of the disclosure.

FIG. 3B illustrates a block diagram of an example of an HBM subsystem including clock gating logic, according to some embodiments of the disclosure.

FIG. 3C illustrates a block diagram of an example of clock gating logic for implementing clock gating techniques, according to some embodiments of the disclosure.

FIG. 3D illustrates a block diagram of an example of a register for storing clock gating configuration information, according to some embodiments of the disclosure.

FIG. 3E illustrates a block diagram of an example of a register for storing timing parameters, according to some embodiments of the disclosure.

FIG. 4 depicts a flow chart illustrating an example of a method for implementing clock gating techniques for memory subsystems, according to some embodiments of the disclosure.

FIG. 5 illustrates a timing diagram of clock gating techniques in a memory subsystem, according to some embodiments of the disclosure.

FIG. 6 illustrates an exemplary computing system in which clock gating techniques for memory subsystems may be implemented, according to some embodiments of the disclosure.

### DETAILED DESCRIPTION

### Overview

Clock gating techniques for memory subsystems as described herein may have the benefit of reduced power consumption. In one example, a memory subsystem that integrates a memory controller on the same die as I/O interface circuitry for communicating with memory may not have a separate physical layer (PHY) between the memory controller and interface. As explained in more detail below, the clock signal (e.g., a double data rate PHY (DFI) clock or other clock signal) that the memory controller generates and provides to the I/O interface circuitry is expected to be free running in existing memory subsystems due to the reliance of training, voltage tracking, and temperature tracking operations on the clock signal.

In contrast, examples described herein include clock gating logic to gate the clock signal from the memory controller when the memory controller interface is idle. The clock gating logic may ungate the clock signal for a duration when it detects that the memory controller has received a memory access request. The duration that the clock is ungated for may be based on timing parameters obtained from the memory controller, such as latency values and/or other timing parameters. Gating the clock signal when the memory controller’s interface with a requester is idle may result in significant power savings in the memory subsystem.

One example in which clock gating techniques for memory subsystems may be implemented is in a high-bandwidth memory (HBM) subsystem. HBM is a high-performance dynamic random-access memory (DRAM) architecture designed to deliver significantly faster data transfer rates than traditional memory. Standard HBM devices typically use an interface defined by a Joint Electron Device Engineering Council (JEDEC) standard, such as an HBM standard and/or a double data rate PHY (DFI) standard. For example, HBM standard specifications define the electrical specifications, physical architecture, command protocols, timing requirements, and packaging configurations for HBM devices and their interfaces. Examples of HBM standard specifications include HBM1 (HBM, JESD235, originally published by JEDEC in October 2013), HBM2 (HBM version 2, JESD235C, originally published by JEDEC in January 2020), or HBM3 (HBM version 3, JESD238B.01, published April 2025), or future versions of HBM. The DFI standard defines the digital interface protocol, signal definitions, and timing relationships between a memory controller and a DDR PHY (such as in the DFI standard specification version 5.2, published October 2024). In one example, a memory subsystem compliant with an HBM standard includes a dedicated HBM physical layer (PHY) on the system-on-chip (SoC)-side, which manages communication between the SoC and the HBM stack.

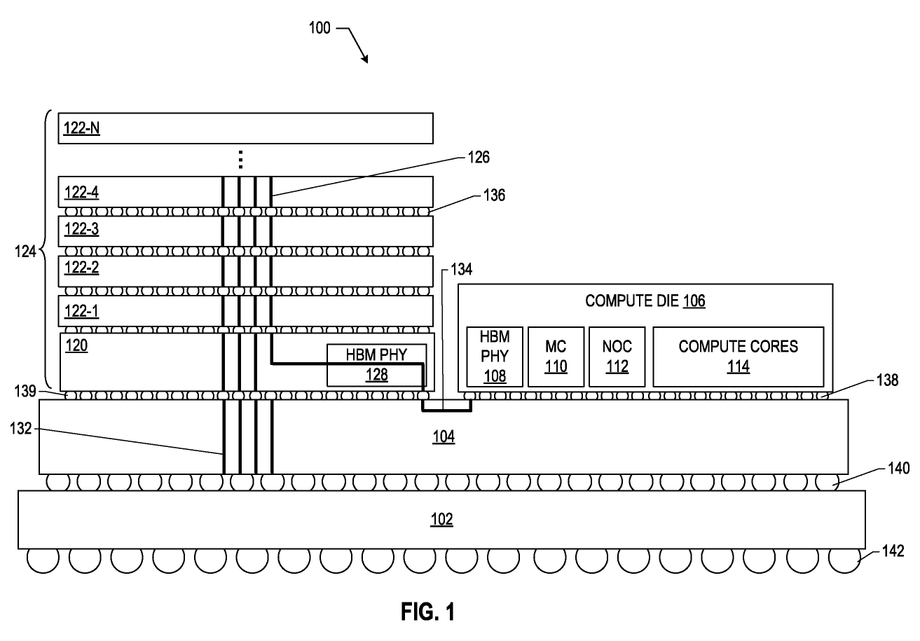

For example, FIG. 1 illustrates an example of a system 100 including an HBM stack 124 coupled with a compute die 106 via an interposer 104. The interposer 104 is over and bonded with a package substrate 102. The package substrate 102 provides electrical routing (e.g., with conductive traces and vias), power distribution, and mechanical support for one or more integrated circuits or interposers mounted on its top surface, while providing larger-pitch conductive interconnects 142 (e.g., solder balls or pins) at its bottom surface to enable coupling with a printed circuit board (PCB). The interposer 104 is coupled with the package substrate 102 via conductive interconnects 140 and typically includes a semiconductor substrate that provides electrical routing (e.g., with conductive traces and vias) between multiple integrated circuits. For example, the interposer 104 provides conductive routing (shown with the interconnects 134) between the compute die 106 and the HBM stack 124. The compute die 106 is bonded with the interposer 104 via conductive interconnects 138. Similarly, the HBM stack 124, which is adjacent to the compute die 106 in FIG. 1, is bonded to the interposer 104 via conductive interconnects 139.

The HBM stack 124 includes a base die 120 and a plurality of DRAM dies 122-1 through 122-N (of which DRAM dies 122-1, 122-2, 122-3, 122-4, and 122-N are shown) stacked over and bonded with one another via conductive interconnects 136. The conductive interconnects 136, 138, 139, 140, and 142 may include solder (e.g., solder joints formed from solder and/or other conductive material(s)). Different sets of conductive interconnects may have the same or different pitches. For example, the interconnects 139 between the HBM stack 124 and the interposer 104 may have a smaller pitch than the conductive interconnects 140 between the interposer 104 and the package substrate. Similarly, the conductive interconnects 138 between the compute die 106 and the interposer 104 may have a smaller pitch than the conductive interconnects 140. Although conductive interconnects 136 are shown between adjacent stacked DRAM dies and between the bottom DRAM die 122-1 and the base die, in some examples, dies of the HBM stack 124 may be coupled via other bonding techniques, such as hybrid bonding.

The HBM stack 124 also includes through-substrate vias (TSVs) 126 that provide vertical conductive connections between the stacked DRAM dies 122-1 through 122-N and the base die 120. Similarly, the interposer 104 includes TSVs 132 that provide vertical conductive connections between the base die 120 and the package substrate 102.

The compute die 106 may be or include an artificial intelligence (AI) accelerator, a graphics processing unit (GPU), a central processing unit (CPU), a neural processing unit (NPU), a tensor processing unit (TPU), a field-programmable gate array (FPGA), an application-specific integrated circuit (ASIC), a digital signal processor (DSP), an SoC, other compute logic, or any combination thereof. In the example illustrated in FIG. 1, the compute die 106 includes compute cores 114, a network-on-chip (NoC) 112, and a memory controller 110. The NoC 112 represents an on‑die interconnect fabric. In one example, the NoC 112 moves command, data, and control traffic between compute cores 114 (or other units of compute logic), the memory subsystem, and input/output (I/O) interfaces. The compute cores 114 represent compute/processing logic for the execution of operations (e.g., arithmetic, logical, and control operations) on data communicated through the NoC 112.

The memory controller 110 includes logic for controlling access to memory, including command logic for generating commands in response to memory access requests and scheduling logic to perform command scheduling. In the example illustrated in FIG. 1, the memory controller 110 is an HBM memory controller to manage command, address, and data for multiple independent HBM channels. The memory controller 110 may also handle interface training and initialization for the memory controller 110 and memory devices (e.g., DRAM dies 122-1 through 122-N).

In the example illustrated in FIG. 1, the compute die 106 also includes an HBM PHY 108. The HBM PHY 108 is physical layer interface circuitry that handles the electrical signaling and protocol conversion between the memory controller 110 and the HBM PHY 128 on the base die 120 of the HBM stack 124. In one example, the HBM PHY 108 provides signal conditioning, timing alignment, and calibration to enable reliable high-speed data transfer through the interposer 104 to the corresponding HBM PHY 128 on the base die 120. The memory controller 110 generates and transmits a clock signal (e.g., a DFI clock) to the HBM PHY 108. In one such example, the DFI clock is the reference clock signal that synchronizes data and command transfers across the DFI between the memory controller 110 and the PHY 108. The DFI clock may serve as the timing reference for DFI protocol signals, including DFI command signals, DFI address signals, DFI write data, and DFI read data, with the HBM PHY 108 using this clock to sample and align transfers to and from the memory controller 110. The DFI clock also provides the timing reference for training and calibration operations for the HBM PHY 108. For example, during initialization, the HBM PHY 108 uses the DFI clock to execute training sequences such as write leveling, read gate training, and delay calibration. The HBM PHY 108 also uses the DFI clock as a timing reference to communicate training signals back to the memory controller 110. The DFI clock further enables ongoing background calibration to compensate for voltage and temperature variations. Therefore, conventional implementations (e.g., based on and compliant with an HBM standard specification) continuously toggle the DFI clock to enable training and initialization operations, which can result in significant power consumption.

### Exemplary system with a custom HBM subsystem

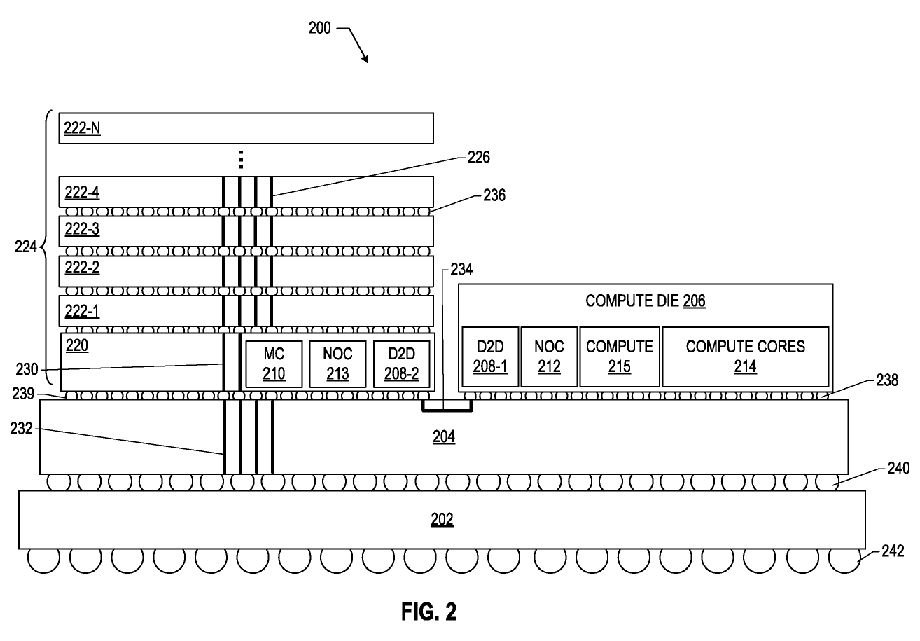

In contrast, FIG. 2 illustrates an exemplary system 200 in which clock gating (e.g., of the DFI clock from the memory controller or other clock signal from a memory controller) may be implemented. Like the system 100 of FIG. 1, the system 200 of FIG. 2 includes an interposer 204 over and coupled with a package substrate 202 via conductive interconnects 240. The interposer includes conductive interconnects 242 on an opposite side for coupling with a PCB. The system 200 includes an HBM stack 224 over and coupled with the interposer 204 via conductive interconnects 239, and a compute die 206 over and coupled with the interposer 204 via conductive interconnects 238. The HBM stack 224 and the compute die 206 are coupled via conductive interconnects (shown with the conductive interconnect 234) in the interposer 204.

The HBM stack 224 includes a base die 220 and a plurality of memory devices 222-1 through 222-N (of which 222-1, 222-2, 222-3, 222-4, and 222-N are shown), where N is a positive integer greater than 1. In some examples, the number of stacked memory devices may include 2, 3, 4, 8, or a greater number of stacked memory devices. The memory devices 222-1 through 222-N and the base die 220 are stacked over one another and coupled together via conductive interconnects 236. TSVs 226 through the memory devices 222-1 through 222-N and base die 230 enable the transmission of signals (e.g., data and control signals) and/or power through the stack 224. TSVs 232 enable the transmission of signals and/or power through the interposer 204. Also, like the system 100 of FIG. 1, the compute die 206 includes compute cores 214 and an NoC 212. The package substrate 202, the interposer 204, the compute die 206, the compute cores 214, the NoC 212, and the memory devices 222-1 through 222-N may be similar to the respective elements of the system 100.

Unlike the system 100, the memory controller 210 in the system 200 is located (e.g., integrated into) the base die 220. Thus, the memory subsystem shown in FIG. 2 may be considered a “custom HBM” solution where the interface between the base die 220 and the compute die 206 may not be compliant with the JEDEC HBM and/or DFI standards. By integrating the memory controller 210 into the base die 220, area on the compute die 206 is available for additional compute logic 215 (which may represent a compute core 214 or other unit of compute logic) located close to memory. Placing additional compute logic 215 close to memory has the benefit of reducing data movement overhead, which can improve bandwidth and efficiency.

Additionally, by integrating the memory controller into the base die, a conventional HBM PHY may be omitted from the compute die 206 and from the base die 220. For example, a conventional HBM PHY can be omitted because the custom, on‑die interface in the base die 220 may use electrical and timing characteristics that do not require PHY‑level training, calibration, or compensation (such as may be needed to manage off‑die signal variability). Instead of a conventional HBM PHY, the compute die 206 includes a die‑to‑die PHY 208‑1 (abbreviated as “D2D” in FIG. 2) and the base die 220 includes a corresponding die‑to‑die PHY 208‑2. The die‑to‑die PHY 208‑1 and the die‑to‑die PHY 208‑2 include physical‑layer interface circuitry for transmitting and receiving die‑to‑die signals between the base die 220 and the compute die 206. Unlike in a conventional HBM subsystem, in which DFI-level command and data signals are communicated between the compute die 206 and the base die 220 via HBM PHYs, the D2D PHYs may operate as standard protocol‑agnostic physical‑layers for communicating memory access requests and data.

In the example illustrated in FIG. 2, the base die also includes an NoC 213. In one example, the NoC 213 represents an on‑die interconnect fabric to enable the communication of command, address, data, and control information between the memory controller 210, the die‑to‑die PHY 208-2, and/or other blocks on the base die 220.

### Exemplary base die

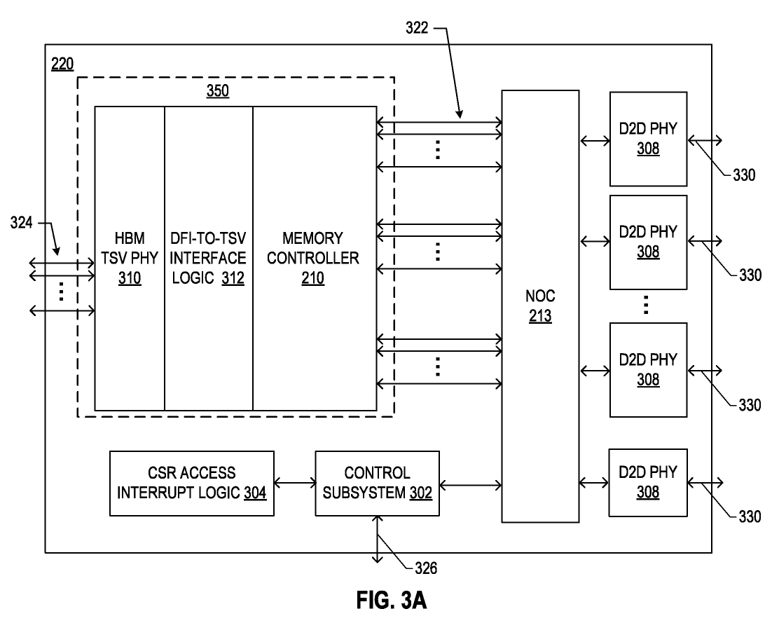

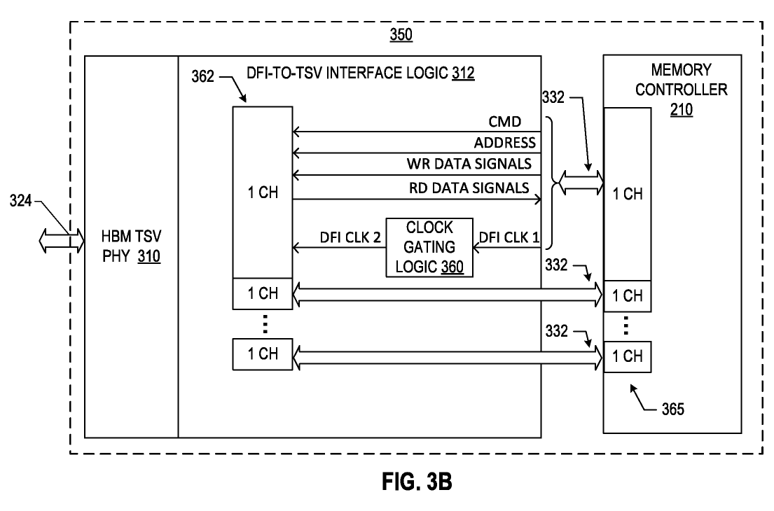

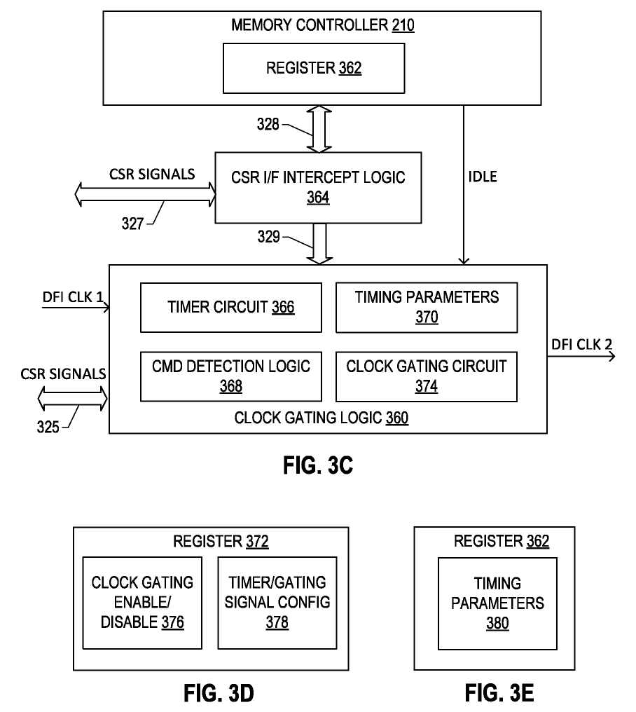

FIG. 3A illustrates a block diagram of an example of the base die 220 with an integrated memory controller 210. As can be seen in FIG. 3A, the base die includes the memory controller 210. The memory controller 210 receives and transmits signals from and to compute logic that is off-die (e.g., to and from the compute die 206) via the D2D PHYs 308 and NoC 213. In one example, the NoC 213 includes I/O interface circuitry to convert wide parallel signals on the memory-side (shown by signal lines 322) to serial signals for transmission through the D2D PHYs 308 over the signal lines 330, and vice versa (i.e., conversion of serial signals from the D2D PHYs 308 to parallel signals transmitted to the memory controller 210).

The base die 220 in FIG. 3A also includes a control subsystem 302. In the example illustrated in FIG. 3A, the control subsystem 302 represents control or management logic for distributing configuration, status, and interrupt signaling to and from blocks of the base die. In one example, the control subsystem 302 handles configuration and status register (CSR) access for initialization and operational control, handles interrupt routing, and communicates with off‑die logic through the NoC 213 and D2D PHY 308. For example, the control subsystem 302 interfaces with CSR access & interrupt logic 304, which provides signaling for configuration and status register accesses and interrupts to and from blocks of the base die. In one example, the control subsystem 302 may also interface with low‑speed management ports such as SPI, I²C, and JTAG (represented by the signal line 326).

The base die 220 illustrated in FIG. 3A also includes an HBM TSV PHY 310. The HBM TSV PHY 310 is physical‑layer interface circuitry that drives and receives the electrical signals from/to the signal lines 324 (e.g., TSVs) coupling the base die to the DRAM dies 222-1 through 222-N. In one example, the HBM TSV PHY 310 performs signal conditioning, level adaptation, timing alignment, and termination. The base die 220 also includes DFI-to-TSV interface logic 312 between the memory controller 210 and the HBM TSV PHY 310. The DFI-to-TSV interface logic 312 (which may be referred to as memory interface logic or interface logic) includes interface circuitry that adapts the DFI commands and data from the memory controller 210 to a signaling format for the memory dies 222-1 through 222-N via the HBM TSV PHY 310. The memory controller 210, DFI-to-TSV interface logic 312, and the HBM TSV PHY 310 make up an HBM subsystem 350 that is shown in more detail in FIG. 3B.

### Exemplary HBM subsystem

FIG. 3B illustrates a block diagram of an example of the HBM subsystem 350 including clock gating logic 360. As can be seen in FIG. 3B, the memory controller 210 transmits and receives per-channel DFI signals to and from the DFI-to-TSV interface logic 312 over signal lines 332. For example, the memory controller 210 includes I/O interface logic 365 to transmit and receive DFI signals over the signal lines 332 for each of a plurality of channels. The number of supported HBM channels may be, for example, 8, 16, 32, or another number of channels. In one example, the DFI signals for each channel include signals for command information, address information (e.g., row, column, etc.), write data (e.g., write data, write enable, error correction code (ECC), and/or other write data signals), read data (e.g., read data, read valid, ECC, DFI sample event, and/or other read data signals). The DFI signals for each channel also include the DFI clock (shown as DFI CLK 1 as transmitted by the memory controller 210 in FIG. 3B).

As mentioned above, unlike in conventional HBM subsystems, a DFI PHY can be omitted from the HBM subsystem 350 in FIG. 3B. As a result, because PHY‑level training or timing‑tracking operations may not be needed, the DFI-to-TSV interface logic 312 between the memory controller and memory devices also may not require a continuously toggled DFI clock. Accordingly, the HBM subsystem 350 includes clock gating logic 360, which receives the DFI clock from the memory controller 210, and gates the DFI clock when it is determined that the memory controller’s interface (e.g., a front-end/system-facing interface, such as the interface with the D2D PHY) is idle. In one example, the HBM subsystem 350 includes clock gating logic 360 for each channel. Thus, although clock gating logic 360 is only shown for one channel in FIG. 3B in order to preserve the clarity of the drawing, the clock gating logic 360 may be replicated for each of a plurality of channels. In another example, clock gating logic 360 may gate the clock signal for all channels for a given HBM stack, or for a subset of channels.

### Exemplary clock gating logic diagram

FIG. 3C illustrates a block diagram of an example of clock gating logic for implementing clock gating techniques as described herein. As can be seen in FIG. 3C, the clock gating logic 360 receives a clock (in this example, DFI clock 1) from the memory controller 210. The clock gating logic 360 also receives CSR signals 325 that include configuration information. For example, the clock gating logic 360 may receive configuration information for the clock gating logic 360, which may be stored in one or more registers on the base die 220. For example, FIG. 3D illustrates an example register 372 that may be included in a base die, and which includes fields indicating clock gating configuration information. The register 372 (which may be a single register or multiple registers) may include fields for each independent channel, for a subset of channels, or for all the channels. As can be seen in FIG. 3D, the register 372 includes a clock gating enable/disable field 376 for storing a value to indicate whether clock gating is enabled or disabled. The register 372 also includes a timer/gating signal configuration field 378 for storing values related to the configuration of the timer or gating signal. Configuration information for the timer or gating signal may include, for example, a margin to adjust the duration that the clock signal is ungated for (e.g., a value to increase or decrease the duration of ungating the clock signal), a minimum idle period for detection of an idle state, and/or other configuration information. The clock gating logic 360 may receive the configuration information from the register 372 (e.g., via a CSR interface with the CSR access and interrupt logic 304 shown in FIG. 3A).

Referring again to FIG. 3C, the clock gating logic 360 also receives CSR signals via signal lines 329 that include timing parameters retrieved from the memory controller 210. For example, during initialization, registers in the memory controller 210, such as the register 362, are programmed to desired values for operation. Referring to FIG. 3E, the register 362 includes timing parameters 380 for memory access operations (e.g., AC timing parameters for memory read and write commands as defined in an HBM specification or other standard specification, or other timing parameters or information). In some examples, while custom HBM subsystems may not comply with all JEDEC-defined rules, the subsystem may implement substantially equivalent timing (e.g., via the DFI-to-TSV interface logic 312). Therefore, the memory controller 210 may store and apply the timing parameters to ensure correct alignment and reliable data capture.

Examples of timing parameters include: a latency value (e.g., read latency (RL) or write latency (WL)), a preamble time (e.g., read preamble time (tRPRE) or write preamble time (tWPRE)), a postamble time (e.g., read postamble time (tRPST) or write postamble time (tWPST)), time between data strobe assertion and data (e.g., tWDQS2DQ or tRDQS2DQ), burst length, and command-to-command timing. Write latency may represent the number of clock cycles (e.g., DFI or DRAM clock cycles) between issuing a write command and the cycle in which the memory controller drives the first valid write data beat onto the data bus. Similarly, read latency may represent the number of clock cycles between issuing a read command and the cycle in which the first valid read data beat is driven onto the data bus. The write‑preamble time may define the minimum number of cycles that the write strobe (e.g., WDQS) is to be asserted before write data is driven onto the data bus, while the write‑postamble time may define the minimum number of cycles that the write strobe is to remain asserted after the final write data beat is driven. The read‑preamble time may define how long the read strobe (e.g., RDQS) is to be asserted before the first valid read data beat, and the read‑postamble time may define how long the read strobe is to remain asserted after the final read data beat. The burst length specifies the number of consecutive data beats transferred on the data bus for each read or write operation (e.g., 8 or another burst length).

Referring again to FIG. 3C, the intercept logic 364 captures configuration values, including timing parameters, sent to the memory controller 210 through the CSR interface and provides those parameters to the clock gating logic 360. For example, the CSR signals over signal lines 327 are sampled or snooped by the intercept logic 364 and sent to the clock gating logic 360 (shown as signal lines 329) in addition to being sent to the memory controller (shown as signal lines 328). As can be seen in FIG. 3C, the clock gating logic 360 may store the intercepted timing parameters 370 locally to be used to generate the clock gating signal (e.g., in a register). In other examples, the clock gating logic 360 may determine the timing parameters with other techniques, or at times other than during initialization (e.g., during operation).

In the example illustrated in FIG. 3C, the clock gating logic 360 also receives one or more signals (shown as IDLE in FIG. 3C) to indicate that an interface of the memory controller 210 is idle (e.g., in an idle state). In one example, detection of an idle memory controller interface is based on an absence of requests from a requester (e.g., an absence of commands at a front-end/system interface) to the memory controller 210. For example, command detection logic 368 may detect whether the memory controller interface is idle or not based on the idle signal. The idle signal may include, or be based on, signal lines transmitting a memory access request to the memory controller 210. In some examples, a determination that a memory controller interface is idle may be based on the absence of transactions for a minimum time (e.g., based on a predetermined time or threshold).

In response to detecting that an interface of the memory controller 210 is idle, the clock gating logic 360 may gate the clock signal. Gating the clock signal may involve, for example, generating a clock enable signal and inputting the clock signal and the clock enable signal into a logic AND gate. For example, a clock gating circuit 374 receives the clock signal (e.g., DFI CLK 1) and the clock enable signal. In one example, the clock gating circuit 374 may include a latch that samples the clock enable signal (e.g., during the low phase of the clock signal) and holds the sampled enable value stable during subsequent clock transitions, preventing the enable signal from changing state while the clock is high. The output of the latch is provided to a first input of a logic AND gate, while the clock signal is provided to a second input of the AND gate, with the AND gate outputting the gated clock output signal (e.g., DFI CLK 2). When the enable signal is asserted high and sampled during a clock low phase, the latch output becomes high, allowing subsequent clock pulses to propagate through the AND gate; when the enable signal is de-asserted low and sampled during a clock low phase, the latch output becomes low, blocking clock pulses from propagating. The clock enable signal may be based on whether an idle state is detected and/or other parameters (such as whether clock gating is enabled based on the register field 376). In other examples, the clock gating circuit 374 may include different or additional circuit elements.

In response to detection of a memory access request to the memory controller, the clock gating logic 360 ungates the clock signal for a duration. For example, in response to the IDLE signal indicating that the memory controller interface is not idle, the clock enable signal may transition from low to high, enabling (e.g., ungating) the clock signal with the clock gating circuit 374 for a duration. For example, the clock enable signal remains high for the predetermined duration as indicated by a timer circuit 366. In one such example, after the duration (and if the memory controller interface is still idle), the clock gating logic 360 gates the clock signal.

The duration that the clock signal is enabled may be based on one or more timing parameters 370. For example, the duration may be based on a latency value associated with a command generated in response to the memory access request. For example, if the memory controller is to generate a write command in response to the memory access request, the duration may be based on the write latency associated with a write command. Similarly, if the memory controller is to generate a read command in response to the memory access request, the duration may be based on the read latency associated with a read command. Thus, in some examples, the clock gating logic 360 is to ungate the clock signal for different durations based on whether the command generated in response to the memory access request is a write command or a read command.

The duration may also, or alternatively, be based on one or more other parameters such as a preamble time, a postamble time, a time between asserting a data strobe and driving data, burst length, and a command-to-command time. Thus, the timer circuit 366 determines the duration for enabling the clock signal, which may be a predetermined time based on one or more timing parameters. The duration may be further based on a value in a register (e.g., the register field 378) to configure the clock gating logic 360, such as a value to indicate a margin to adjust the duration by.

Thus, FIG. 3C illustrates one example of clock gating logic 360 for implementing clock gating techniques for memory subsystems. In one example, the clock gating logic 360 may independently gate and ungate the clock signal for each of a plurality of memory channels. For example, the base die 220 may include a separate instance of the clock gating logic 360 for each channel.

Although the example illustrated in FIG. 3C depicts clock gating for a DFI clock, the clock gating techniques described herein may be used for gating other clock signals in memory subsystems. Additionally, although some examples refer specifically to HBM, the clock gating techniques may apply to other memory architectures.

### Exemplary method for implementing clock gating techniques for memory subsystems

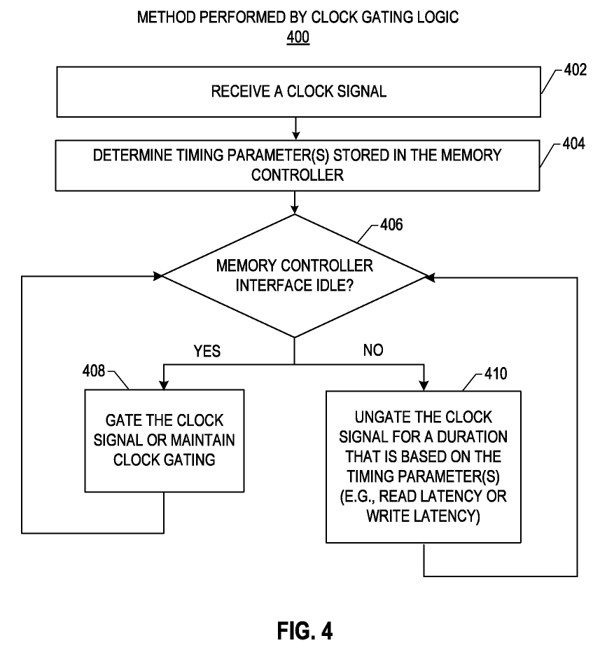

FIG. 4 depicts a flow chart illustrating an example of a method 400 for implementing clock gating techniques for memory subsystems. The method 400 may be performed by hardware (e.g., circuitry), such as by interface logic (e.g., such as the DFI-to-TSV interface logic 312 of FIG. 3B, which may include the clock gating logic 360 and the CSR I/F intercept logic 364 shown in FIG. 3C).

The method 400 begins with receiving a clock signal from a memory controller (e.g., from a clock generator of a memory controller), in 402. For example, referring to FIG. 3B, the DFI-to-TSV interface logic 312 receives the DFI CLK 1.

The method 400 continues with determining timing parameter(s) stored in the memory controller, in 404. Determining timing parameters stored in the memory controller may involve, for example, intercepting on write operations to registers in the memory controller that store the timing parameters. For example, the intercept logic 364 may sample (e.g., read, snoop, or otherwise obtain) the signals being sent to the memory controller to program one or more registers that store timing parameters, such as the register 362 of FIG. 3E.

The method 400 continues with determining whether an interface of the memory controller is idle, in 406. Determining whether the memory interface is idle may involve, for example, monitoring a transaction/front-end/system bus or interface between the memory controller and compute logic. For example, referring to FIG. 3A, command signals received by the NOC 213 may be observed to determine if an interface of the memory controller 210 is idle.

If the memory controller interface is idle, the method 400 involves gating the clock signal, in 408. Gating of the clock signal may be performed with clock gating logic, such as the clock gating logic 360 of FIG. 3C.

If the memory controller interface is not idle, the method 400 may involve ungating (e.g., enabling) the clock signal for a duration that is based on the timing parameter(s), in 410. For example, the duration may be based on a latency value from a register in the memory controller (e.g., as intercepted and read during initialization) and/or other parameters. After the duration, the method may involve gating the clock signal (in 408) if it is determined that the memory controller interface is idle, in 406.

### Exemplary timing diagram depicting clock gating techniques in a memory subsystem

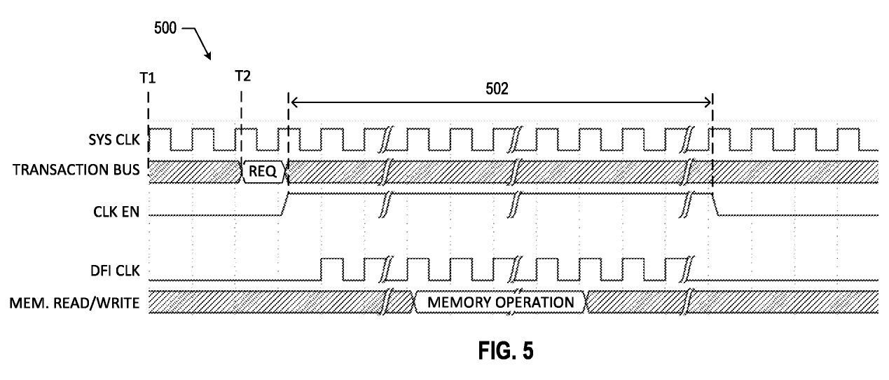

FIG. 5 illustrates a timing diagram 500 of clock gating techniques in a memory subsystem. The timing diagram 500 of FIG. 5 depicts a system clock (SYS CLK), which may represent a front-end/system-side clock forwarded from the compute die 206 through the die-to-die PHY 308 of the base die 220. In one such example, the system clock may be used to clock transactions received from the compute die 206 over the transaction/front-end bus (TRANSACTION BUS). The timing diagram 500 also depicts a clock enable signal (CLK EN) to enable a clock signal (depicted here as DFI CLK). As discussed above, the clock enable signal may be generated by the clock gating logic 360 based on a determination of whether the memory controller interface is idle. The timing diagram 500 also depicts a memory bus over which memory read or write commands may be sent.

As can be seen in the timing diagram 500, at time T1 the clock enable signal is de-asserted and the DFI clock is gated . At time T2, a memory request (REQ) is detected on the transaction bus. In response to detecting the memory request, the clock enable signal is asserted and the DFI clock is ungated. The DFI clock remains ungated for a duration 502 that is based on one or more timing parameters, such as a latency of the memory operation performed in response to receipt of the memory access request. In the example illustrated in FIG. 5, the clock enable signal de-asserts after the duration 502 and in response to an absence of additional memory access requests on the transaction bus.

Thus, clock-gating techniques for memory subsystems may enable significant reductions in power consumption by gating a clock signal from the memory controller during idle intervals while preserving correct protocol timing for memory operations. In one example, clock gating logic ungates the clock signal in response to detecting receipt of a memory access command by the memory controller. The clock gating logic determines how long to enable the clock signal based on timing parameters obtained from the memory controller. Therefore, the clock-gating techniques described herein may reduce toggling of the clock signal from the memory controller, which may result in significant power savings.

Although specific examples described above refer to HBM subsystems, the clock gating techniques may apply to other memory architectures (e.g., memory subsystems in which the memory controller is integrated onto the same die as the memory interface). For example, the clock-gating techniques described herein may also be implemented in non-volatile memory systems, such as NAND flash memory systems, NOR flash devices, phase-change memory (PCM) systems, resistive RAM (ReRAM), magnetic RAM (MRAM), or other non-volatile memory architectures.

### Exemplary host device

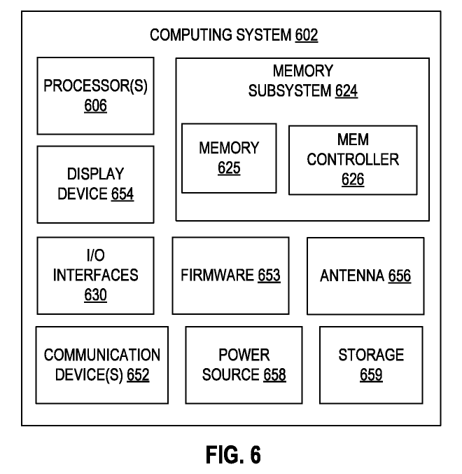

FIG. 6 illustrates an exemplary computing system 602 in which clock gating techniques for memory subsystems may be implemented. In some examples, the computing system 602 may be or include a system-on-a-chip (SoC) device. The computing system 602 may include one or more processors 606, such as CPUs, GPUs, digital signal processors (DSPs), microcontrollers, application-specific integrated circuits (ASICs), field-programmable gate arrays (FPGAs), network processors, audio processors, image processors, cryptographic processors, artificial intelligence accelerators, tensor processing units (TPUs), and/or other processors. The processors 606 may be an example of, or included in, the compute die 206 of FIG. 2. The computing system 602 includes a memory subsystem 624, which includes a memory controller 626 and memory 625. The memory controller 626 may be an example of the memory controller 210 of FIG. 2. The memory 625 may be an example of the memory devices 222-1 through 222-N of FIG. 2. The memory 625 may store data and instructions, including instructions for executing an operating system. The memory 625 is an example of computer-readable media that may store data and/or instructions.

In addition to the memory 625, the system 602 may include storage 659, which includes non-volatile storage devices for persistent data retention. For example, the storage 659 may include solid-state drives (SSDs), hard disk drives (HDDs), flash memory devices, or other non-volatile storage technologies. The storage 659 may provide long-term data storage capabilities for the computing system 602 and may interface with other system components through storage protocols such as Serial Advanced Technology Attachment (SATA), Non-Volatile Memory Express (NVMe), or other suitable storage interfaces.

The computing system 602 includes I/O interfaces 630 such as Universal Serial Bus (USB), Thunderbolt, Serial Advanced Technology Attachment (SATA), Peripheral Component Interconnect Express (PCIe), Non-Volatile Memory Express (NVMe), Compute Express Link (CXL), Serial Peripheral Interface (SPI), Inter-Integrated Circuit (I2C), Ethernet, wireless communication interfaces including Wi-Fi and Bluetooth, High-Definition Multimedia Interface (HDMI), DisplayPort, and various proprietary or industry-standard communication protocols for connecting peripheral devices, storage systems, and network components. The computing system 602 includes firmware 653, which includes executable code stored in non-volatile memory that configures and controls hardware components during initialization and runtime operations of the system 602.

The computing system 602 includes one or more power sources 658, which are components configured to provide electrical energy to support the operation of the computing system. Power sources 658 may include an alternating current (AC) power supply and a battery. The computing system 602 may include one or more antennas 656 configured to enable wireless communication with external devices or networks. The computing system 602 may include one or more communication devices 652 comprising wireless and wired communication components such as Wi-Fi transceivers, Bluetooth modules, cellular modems, Ethernet controllers, or radio frequency communication circuits for enabling data exchange with external devices, networks, and communication systems. The communication devices 652 may facilitate various communication protocols and standards for transmitting and receiving data across different network infrastructures and communication mediums. The computing system 602 may include a display device 654 comprising visual output components such as liquid crystal displays (LCD), light-emitting diode (LED) displays, or organic light-emitting diode (OLED) displays, for presenting graphical information, text, images, and user interface elements to a user.

### Select examples

Example 1 provides a die (e.g., base die or other die) with logic for accessing memory, the die including a memory controller; I/O interface circuitry to receive a clock signal (e.g., DFI clock or other clock signal from a memory controller) from the memory controller; and clock gating logic to: in response to detection of an idle memory controller interface, gate the clock signal, and in response to detection of a memory access request to the memory controller interface, ungate the clock signal for a duration, where the duration is based on a latency value associated with a command generated in response to the memory access request.

Example 2 provides the die of example 1, where: the clock gating logic is to: after the duration and in response to detection of the idle memory controller interface, gate the clock signal (e.g., re-gate the DFI clock after the duration/expiration of the duration if the memory controller interface is idle).

Example 3 provides the die of examples 1 or 2, where: the clock gating logic is to ungate the clock signal for different durations based on whether the command is a write command or a read command.

Example 4 provides the die of any one of examples 1-3, where: the duration is based on the latency value from a register in the memory controller (e.g., as intercepted and read during initialization).

Example 5 provides the die of example 4, where the register is a first register, and where: the die further includes a second register to store the latency value from the first register in the memory controller (e.g., a local register to store the timing parameters intercepted during initialization).

Example 6 provides the die of any one of examples 1-5, where: the duration is further based on one or more of: a preamble time associated with the command and a postamble time associated with the command (e.g., tWPRE1, tWPST1, tRPRE, tRPST).

Example 7 provides the die of any one of examples 1-6, where: the duration is further based on a timing parameter for the command indicating a time between asserting a data strobe and driving data on data signal lines relative to the data strobe (e.g., tWDQS2DQ or tRDQS2DQ).

Example 8 provides the die of any one of examples 1-7, where: the duration is further based on a burst length.

Example 9 provides the die of any one of examples 1-8, where: the duration is further based on a command-to-command timing parameter.

Example 10 provides the die of any one of examples 1-9, where: the clock gating logic includes a timer circuit to determine the duration, and the duration is further based on a value in a register to indicate a margin to adjust the duration by.

Example 11 provides the die of any one of examples 1-10, where: the detection of the idle memory controller interface is based on an absence of requests from a requester (e.g., an idle front-end/system-facing interface or other transaction interface).

Example 12 provides the die of any one of examples 1-11, where: the clock gating logic is to independently gate and ungate the clock signal for each of a plurality of memory channels.

Example 13 provides the die of any one of examples 1-12, further including one or more registers to store clock gating configuration values, including one or more of: an enable or disable value, a margin to adjust the duration by, and a minimum idle period for detection of an idle state (config. registers may be per channel or apply to all or a subset of channels).

Example 14 provides the die of any one of examples 1-13, where: the die is a base die, the memory includes HBM devices, and the clock signal includes a double data rate (DDR) PHY (DFI) clock signal.

Example 15 provides the die of any one of examples 1-14, where: the signals include logical command signals (e.g., DFI command signals/digital command signals) for the command, and the die further includes a physical layer to transmit physical command signals (e.g., DRAM/HBM command signals) to the memory based on the logical command signals.

Example 16 provides interface logic between a memory controller and a memory device, the interface logic including I/O interface circuitry to receive signals from the memory controller, where the signals include command signals for a command and an associated clock signal (DFI clock); and clock gating logic to: in response to detection of an idle state of the memory controller, gate the clock signal, and in response to detection of a memory access request to the memory controller, ungate the clock signal for a duration, where the duration is based on a latency value associated with the command generated in response to the memory access request.

Example 17 provides the interface logic of example 16, where: the clock gating logic is to: after the duration and in response to detection of the idle state, gate the clock signal.

Example 18 provides the interface logic of examples 16 or 17, where: the clock gating logic is to ungate the clock signal for different durations based on whether the command is a write command or a read command.

Example 19 provides the interface logic of any one of examples 16-18, where: the duration is based on the latency value from a register in the memory controller.

Example 20 provides the interface logic of any one of examples 16-19, where: the duration is further based on one or more of: a preamble time associated with the command and a postamble time associated with the command.

Example 21 provides the interface logic of any one of examples 16-20, where: the duration is further based on a timing parameter for the command indicating a time between asserting a data strobe and driving data on data signal lines relative to the data strobe.

Example 22 provides the interface logic of any one of examples 16-21, where: the duration is further based on a burst length.

Example 23 provides the interface logic of any one of examples 16-22, where: the duration is further based on a command-to-command timing parameter.

Example 24 provides the interface logic of any one of examples 16-23, where: the clock gating logic includes a timer circuit to determine the duration, and the duration is further based on a value in a register to indicate a margin to adjust the duration by.

Example 25 provides the interface logic of any one of examples 16-24, where: the detection of the idle state is based on an absence of requests from a requester to the memory controller.

Example 26 provides the interface logic of any one of examples 16-25, where: the clock gating logic is to independently gate and ungate the clock signal for each of a plurality of memory channels.

Example 27 provides the interface logic of any one of examples 16-26, where: the command signals include logical command signals for the command.

Example 28 provides a microelectronic assembly including a HBM stack, the HBM stack including a plurality of stacked DRAM dies; a base die below and bonded with the plurality of stacked DRAM dies, where the base die includes a memory controller including a clock generator to generate a clock signal, command logic to generate a command in response to a memory access request; input/output (I/O) interface circuitry to receive the clock signal and the command, and clock gating logic to: in response to detection of an idle memory controller interface, gate the clock signal, and in response to detection of the memory access request, ungate the clock signal for a duration based on a timing parameter associated with the command.

Example 29 provides the microelectronic assembly of example 28, where: the clock gating logic is to: after the duration and in response to the detection of the idle memory controller interface, gate the clock signal.

Example 30 provides the microelectronic assembly of examples 28 or 29, where: the clock gating logic is to ungate the clock signal for different durations based on whether the command is a write command or a read command.

Example 31 provides the microelectronic assembly of any one of examples 28-30, where: the duration is based on the latency value from a register in the memory controller.

Example 32 provides the microelectronic assembly of example 31, where the register is a first register, and where: the base die further includes a second register to store the latency value from the first register in the memory controller.

Example 33 provides the microelectronic assembly of any one of examples 28-32, where: the duration is further based on one or more of: a preamble time associated with the command and a postamble time associated with the command.

Example 34 provides the microelectronic assembly of any one of examples 28-32, where: the duration is further based on a timing parameter for the command indicating a time between asserting a data strobe and driving data on data signal lines relative to the data strobe.

Example 35 provides the microelectronic assembly of any one of examples 28-34, where: the duration is further based on a burst length.

Example 36 provides the microelectronic assembly of any one of examples 28-35, where: the duration is further based on a command-to-command timing parameter.

Example 37 provides the microelectronic assembly of any one of examples 28-36, where: the clock gating logic includes a timer circuit to determine the duration, and the duration is further based on a value in a register to indicate a margin to adjust the duration by.

Example 38 provides the microelectronic assembly of any one of examples 28-37, where: the detection of the idle memory controller interface is based on an absence of requests from a requester.

Example 39 provides the microelectronic assembly of any one of examples 28-38, where: the clock gating logic is to independently gate and ungate the clock signal for each of a plurality of memory channels.

Example 40 provides the microelectronic assembly of any one of examples 28-39, further including one or more registers to store clock gating configuration values, including one or more of: an enable or disable value, a margin to adjust the duration by, and a minimum idle period for detection of an idle state.

Example 41 provides the microelectronic assembly of any one of examples 28-40, where: the signals include logical command signals for the command, and the base die further includes a physical layer to transmit physical command signals to the plurality of stacked DRAM dies based on the logical command signals.

Example 42 provides a system including a first die coupled with an interposer, where the first die includes compute logic; and a second die coupled with the interposer, where the second die includes a memory controller, input/output (I/O) interface circuitry to receive a clock signal from the memory controller, and clock gating logic to: in response to detection of an idle memory controller interface, gate the clock signal, and in response to detection of a memory access request to the memory controller, ungate the clock signal for a duration, where the duration is based on a latency value stored in the memory controller.

Example 43 provides the system of example 42, where: the second die is a base die in a HBM stack, where the HBM stack includes a plurality of stacked DRAM dies, and the clock signal is a double data rate physical layer (DDR PHY (DFI)) clock signal.

Example 44 provides the system of examples 42 or 43, where: the clock gating logic is to: after the duration and in response to detection of the idle memory controller interface, gate the clock signal.

Example 45 provides the system of any one of examples 42-44, where: the clock gating logic is to ungate the clock signal for different durations based on whether the command is a write command or a read command.

Example 46 provides the system of any one of examples 42-45, where: the duration is based on the latency value from a register in the memory controller.

Example 47 provides the system of example 46, where the register is a first register, and where: the die further includes a second register to store the latency value from the first register in the memory controller.

Example 48 provides the system of any one of examples 42-47, where: the duration is further based on one or more of: a preamble time associated with the command and a postamble time associated with the command.

Example 49 provides the system of any one of examples 42-48, where: the duration is further based on a timing parameter for the command indicating a time between asserting a data strobe and driving data on data signal lines relative to the data strobe.

Example 50 provides the system of any one of examples 42-48, where: the duration is further based on a burst length.

Example 51 provides the system of any one of examples 42-50, where: the duration is further based on a command-to-command timing parameter.

Example 52 provides the system of any one of examples 42-51, where: the clock gating logic includes a timer circuit to determine the duration, and the duration is further based on a value in a register to indicate a margin to adjust the duration by.

Example 53 provides the system of any one of examples 42-52, where: the detection of the idle memory controller interface is based on an absence of requests from the first die.

Example 54 provides the system of any one of examples 42-53, where: the clock gating logic is to independently gate and ungate the clock signal for each of a plurality of memory channels.

Example 55 provides the system of any one of examples 42-54, further including one or more registers to store clock gating configuration values, including one or more of: an enable or disable value, a margin to adjust the duration by, and a minimum idle period for detection of an idle state.

Example 56 provides the system of any one of examples 42-55, where: the signals include logical command signals for the command, and the second die further includes a physical layer to transmit physical command signals to memory based on the logical command signals.

Example 57 provides a method of performing clock gating in a memory subsystem including a memory controller and memory interface logic on the same die, where the memory controller includes a front-end interface to receive memory access requests from a requester, and where the method includes receiving, at the memory interface logic between the memory controller and a memory device, a clock signal from the memory controller; in response to determining the front-end interface of the memory controller is idle, gating the clock signal; detecting a memory access request received by the memory controller at the front-end interface, where the memory controller is to generate a command based on the memory access request; in response to detecting the memory access request, ungating the clock signal for a duration based on a timing parameter associated with the command; and gating the clock signal after the duration.

Example 58 provides the method of example 57, where: the timing parameter includes one or more of: a latency value, a preamble time, a postamble time, a time between data strobe assertion and data driven on data signal lines, a burst length, and a command-to-command parameter.

Example 59 provides the method of examples 57 or 58, where: determining the front-end interface of the memory controller is idle includes detecting an absence of requests at the front-end interface for a predetermined time.

Example 60 provides the method of any one of examples 57-59, further including intercepting a register write request to the memory controller to determine the timing parameter.

Example 61 provides a method of performing clock gating in a HBM subsystem, the method including receiving, at an input/output (I/O) interface between a memory controller and a HBM device, a double data rate physical layer (DDR PHY (DFI)) clock signal from the memory controller; in response to determining an interface of the memory controller is idle, gating the DFI clock signal; detecting a memory access request received by the memory controller from a requester, where the memory controller is to generate a command based on the memory access request; in response to detecting the memory access request, ungating the DFI clock signal for a duration based on a latency value associated with the command; and gating the clock signal after the duration.

Example 62 provides the method of example 61, where: the timing parameter includes one or more of: a latency value, a preamble time, a postamble time, a time between data strobe assertion and data driven on data signal lines, a burst length, and a command-to-command parameter.

Example 63 provides the method of examples 61 or 62, where: determining the interface of the memory controller is idle includes detecting an absence of requests at the interface for a predetermined time.

Example 64 provides the method of any one of examples 61-63, further including intercepting a register write request to the memory controller to determine the latency value.

Example 65 provides a die with logic for accessing memory, the die including a memory controller; means for receiving a clock signal from the memory controller; means for gating the clock signal in response to detection of an idle memory controller interface; and means for, in response to detection of a memory access request to the memory controller interface: ungating the clock signal for a duration, where the duration is based on a latency value associated with a command generated in response to the memory access request.

Example 66 provides the die of example 65, further including means for, after the duration and in response to the detection of the idle memory controller interface, gating the clock signal.

Example 67 provides the die of examples 65 or 66, where: the means for ungating the clock signal includes means for: ungating the clock signal for different durations based on whether the command is a write command or a read command.

Example 68 provides the die of any one of examples 65-67, where: the duration is based on the latency value from a register in the memory controller.

Example 69 provides the die of example 68, where the register is a first register, and where: the die further includes a second register to store the latency value from the first register in the memory controller.

Example 70 provides the die of any one of examples 65-69, where: the duration is further based on one or more of: a preamble time associated with the command and a postamble time associated with the command.

Example 71 provides the die of any one of examples 65-70, where: the duration is further based on a timing parameter for the command indicating a time between asserting a data strobe and driving data on data signal lines relative to the data strobe.

Example 72 provides the die of any one of examples 65-71, where: the duration is further based on a burst length.

Example 73 provides the die of any one of examples 65-72, where: the duration is further based on a command-to-command timing parameter.

Example 74 provides the die of any one of examples 65-73, where: the duration is further based on a value in a register to indicate a margin to adjust the duration by.

Example 75 provides the die of any one of examples 65-74, where: the detection of the idle memory controller interface is based on an absence of requests from a requester.

Example 76 provides the die of any one of examples 65-75, further including means for independently gating and ungating the clock signal for each of a plurality of memory channels.

Example 77 provides the die of any one of examples 65-76, further including means for storing clock gating configuration values, including one or more of: an enable or disable value, a margin to adjust the duration by, and a minimum idle period for the detection of the idle memory controller interface.

Example 78 provides the die of any one of examples 65-77, where: the die is a base die, the memory includes high-bandwidth memory (HBM) devices, and the clock signal includes a double data rate (DDR) PHY (DFI) clock signal.

Example 79 provides the die of any one of examples 65-78, further including means for receiving logical command signals for the command, and means for transmitting physical command signals to the memory based on the logical command signals.

### Variations and other notes

The detailed description, such as the "Select examples" section, provides various examples of the embodiments disclosed herein.

As used herein, the term "coupled to" or "coupled with" refers to a relationship between electronic components or circuit elements wherein the components are in electronic communication with one another and are capable of transmitting and/or receiving electrical signals between them. The term "coupled to" does not require a direct physical or electrical connection between the coupled components. Rather, "coupled to" can encompass arrangements where the components are connected through one or more intervening elements, components, circuits, or transmission paths. For example, a first component may be "coupled to" a second component through intermediate components such as resistors, capacitors, inductors, transistors, logic gates, buses, transformers, or other electronic components, or through intermediate transmission paths, while still maintaining the capability for electronic communication between the first and second components.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

For purposes of explanation, specific numbers, materials, and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well-known features are omitted or simplified in order not to obscure the illustrative implementations.

Further, references are made to the accompanying drawings that form a part hereof, and in which are shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the disclosed subject matter. However, the order of description should not be construed as implying that these operations are necessarily order-dependent. In particular, these operations may not be performed in the order of presentation. Operations described may be performed in a different order from the described embodiment. Various additional operations may be performed or described operations may be omitted in additional embodiments.

For the purposes of the present disclosure, the phrase “A or B” or the phrase "A and/or B" means (A), (B), or (A and B). For the purposes of the present disclosure, the phrase “A, B, or C” or the phrase "A, B, and/or C" means (A), (B), (C), (A and B), (A and C), (B and C), or (A, B, and C). The term "between," when used with reference to measurement ranges, is inclusive of the ends of the measurement ranges.

The description uses the phrases "in an embodiment" or "in embodiments," which may each refer to one or more of the same or different embodiments. The terms "comprising," "including," "having," and the like, as used with respect to embodiments of the present disclosure, are synonymous. The disclosure may use perspective-based descriptions such as "above," "below," "top," "bottom," and "side" to explain various features of the drawings, but these terms are simply for ease of discussion, and do not imply a desired or required orientation. The accompanying drawings are not necessarily drawn to scale. Unless otherwise specified, the use of the ordinal adjectives “first,” “second,” and “third,” etc., to describe a common object, merely indicates that different instances of like objects are being referred to and are not intended to imply that the objects so described must be in a given sequence, either temporally, spatially, in ranking, or in any other manner.

In the following detailed description, various aspects of the illustrative implementations will be described using terms commonly employed by those skilled in the art to convey the substance of their work to others skilled in the art.

The terms “substantially,” “close,” “approximately,” “near,” and “about,” generally refer to being within +/- 20% of a target value as described herein or as known in the art. Similarly, terms indicating orientation of various elements, e.g., “coplanar,” “perpendicular,” “orthogonal,” “parallel,” or any other angle between the elements, generally refer to being within +/- 5-20% of a target value as described herein or as known in the art.

In addition, the terms “comprise,” “comprising,” “include,” “including,” “have,” “having” or any other variation thereof, are intended to cover a non-exclusive inclusion. For example, a method, process, or device, that comprises a list of elements is not necessarily limited to only those elements but may include other elements not expressly listed or inherent to such method, process, or device. Also, the term “or” refers to an inclusive “or” and not to an exclusive “or.”

The systems, methods and devices of this disclosure each have several innovative aspects, no single one of which is solely responsible for all desirable attributes disclosed herein. Details of one or more implementations of the subject matter described in this specification are set forth in the description and the accompanying drawings.

1. A die with logic for accessing memory, the die comprising:
a memory controller;
input/output (I/O) interface circuitry to receive a clock signal from the memory controller; and
clock gating logic to:
in response to detection of an idle memory controller interface, gate the clock signal, and
in response to detection of a memory access request to the memory controller interface, ungate the clock signal for a duration, wherein the duration is based on a latency value associated with a command generated in response to the memory access request.

2. The die of claim 1, wherein:
the clock gating logic is to: after the duration and in response to the detection of the idle memory controller interface, gate the clock signal.

3. The die of claim 1, wherein:
the clock gating logic is to ungate the clock signal for different durations based on whether the command is a write command or a read command.

4. The die of claim 1, wherein:
the duration is based on the latency value from a register in the memory controller.

5. The die of claim 4, wherein the register is a first register, and wherein:
the die further comprises:
a second register to store the latency value from the first register in the memory controller.

6. The die of claim 1, wherein:
the duration is further based on one or more of: a preamble time associated with the command and a postamble time associated with the command.

7. The die of claim 1, wherein:
the duration is further based on a timing parameter for the command indicating a time between asserting a data strobe and driving data on data signal lines relative to the data strobe.

8. The die of claim 1, wherein:
the duration is further based on a burst length.

9. The die of claim 1, wherein:
the duration is further based on a command-to-command timing parameter.

10. The die of claim 1, wherein:
the clock gating logic comprises a timer circuit to determine the duration, and
the duration is further based on a value in a register to indicate a margin to adjust the duration by.

11. The die of claim 1, wherein:
the detection of the idle memory controller interface is based on an absence of requests from a requester.

12. The die of claim 1, wherein:
the clock gating logic is to independently gate and ungate the clock signal for each of a plurality of memory channels.

13. The die of claim 1, further comprising:
one or more registers to store clock gating configuration values, including one or more of: an enable or disable value, a margin to adjust the duration by, and a minimum idle period for the detection of the idle memory controller interface.

14. The die of claim 1, wherein:
the die is a base die,
the memory comprises high-bandwidth memory (HBM) devices, and
the clock signal comprises a double data rate (DDR) PHY (DFI) clock signal.

15. The die of claim 1, wherein:
the I/O interface circuitry is to receive logical command signals for the command, and
the die further comprises a physical layer to transmit physical command signals to the memory based on the logical command signals.

16. Interface logic between a memory controller and a memory device, the interface logic comprising:
input/output (I/O) interface circuitry to receive signals from the memory controller, wherein the signals comprise command signals for a command and an associated clock signal; and
clock gating logic to:
in response to detection of an idle state of the memory controller, gate the clock signal, and
in response to detection of a memory access request to the memory controller, ungate the clock signal for a duration, wherein the duration is based on a latency value associated with the command generated in response to the memory access request.

17. The interface logic of claim 16, wherein:
the clock gating logic is to: after the duration and in response to detection of the idle state, gate the clock signal.

18. The interface logic of claim 16, wherein:
the clock gating logic is to ungate the clock signal for different durations based on whether the command is a write command or a read command.

19. A microelectronic assembly comprising a high-bandwidth memory (HBM) stack, the HBM stack comprising:
a plurality of stacked dynamic random-access memory (DRAM) dies; and
a base die below and bonded with the plurality of stacked DRAM dies, wherein the base die comprises:
a memory controller comprising:
a clock generator to generate a clock signal, and
command logic to generate a command in response to a memory access request;
input/output (I/O) interface circuitry to receive the clock signal and the command, and
clock gating logic to:
in response to detection of an idle memory controller interface, gate the clock signal, and
in response to detection of the memory access request, ungate the clock signal for a duration based on a timing parameter associated with the command.

20. The microelectronic assembly of claim 19, wherein:
the clock gating logic is to: after the duration and in response to the detection of the idle memory controller interface, gate the clock signal.

21. A die with logic for accessing memory, the die comprising:
a memory controller;
means for receiving a clock signal from the memory controller;
means for gating the clock signal in response to detection of an idle memory controller interface; and
means for, in response to detection of a memory access request to the memory controller interface: ungating the clock signal for a duration, wherein the duration is based on a latency value associated with a command generated in response to the memory access request.

22. The die of claim 21, further comprising:
means for, after the duration and in response to the detection of the idle memory controller interface, gating the clock signal.
